(19) United States
(12) Patent Application Publication
(10) Pub. No.: US 2002/0031890 A1
(43) Pub. Date: Mar. 14, 2002

(54) Semiconductor device of STI structure and method of fabricating MOS transistors having consistent threshold voltages

(76) Inventors: Takayuki Watanabe, Shiga (JP); Junji Kiyono, Shiga (JP)

Correspondence Address: HELFGOTT & KARAS P.C., 60th Floor, Empire State Building, New York, NY, 10118-0110, US

(21) Appl. No.: 09/939,458

(22) Filed: Aug. 24, 2001

(30) Foreign Application Priority Data
Aug. 28, 2000 (JP) 2000-256591

(51) Int. Cl. H01L 21/336

(52) U.S. Cl. 438/296

(57) ABSTRACT

Isolation trenches, formed on a silicon substrate, are lined with a silicon nitride liner and filled with an insulating filler for isolating MOS transistors from each other. For each MOS transistor, an impurity-doped channel region is formed between adjacent trenches, the channel region having a conductivity type equal to conductivity type of the substrate and a concentration higher than a concentration of the substrate. For each channel region, a pair of heavily doped impurity regions are formed in locations close to the adjacent trenches. The heavily doped regions have a concentration higher than the concentration of the channel region.

### BACKGROUND OF THE INVENTION

1. Field of the Invention

The present invention relates to a semiconductor device and a method of forming a trench isolation structure on a silicon substrate for isolating MOS transistors, where the trenches are lined with silicon nitride.

2. Description of the Related Art

Shallow trench isolation structures are used to isolate circuit elements on an LSI chip. Prior to filling the trenches with a silicon dioxide filler, the trenches are lined with a silicon nitride liner to relief the stress caused by oxidation. As shown in FIG. 1, a prior art integrated NMOS transistor circuit of the STI structure is fabricated on a p-type silicon substrate 1. For isolating NMOS transistors from each other, isolation trenches 2 are formed on the principle surface of substrate 1. A thermal oxidation process is performed to cover the inside walls of the trenches with a thermal oxide liner 6 to relief the damage which may have been produced during the trench formation. Trenches 2 are further lined with a silicon nitride liner 8 and filled with a silicon dioxide filler 10. The channel region regions 12 of the NMOS transistors are formed by doping the silicon substrate 1 with a p-type impurity (i.e., boron) with a concentration higher than the concentration of the substrate. Gate oxide layers 14 are formed on the channel regions 12 and gate electrodes 16 of polysilicon and metal suicides is deposited across the wafer. On opposite ends of each of the channel regions 12 are provided diffused regions of source and drain, not shown. Since the gate electrodes 16 are provided not only on the channel regions 12 but on the side regions of trenches 2, the edge portions 12a of each channel region are subjected not only to electrical fields of vertical component but to horizontal component, or “fringing fields” when a voltage is applied to the gate. In addition, during a thermal treatment process that is performed after the channel regions are created, boron migrates from the channel regions 12 into the thermal oxide liner 6, resulting in a decrease in the boron concentration of the channel regions. As a result, when the gate voltage is increased, channel regions 12 enter a conducting state earlier at their edge portions 12a than they do at their center portions. This causes a lowering of the threshold voltage of the NMOS transistor and variability of threshold voltages. The PMOS structures may likewise suffer from similar problems due to the presence of fringing fields although their channel region impurities (i.e., phosphorus and arsenic) do not migrate during thermal oxidation.

Japanese Patent Publication 11-54712 discloses a dynamic random access memory (DRAM) comprised of an array of NMOS cells and a PMOS peripheral circuitry on a silicon substrate. This prior art solves the channel region-edge problem of the DRAM by masking the NMOS cells with a resist after trenches are formed on the substrate and injecting phosphorus ions into the PMOS circuitry at an angle to the vertical so that an n-type impurity is doped on the sidewalls and bottom of the trenches. The use of skewed injection is allowed for the PMOS peripheral circuitry because of its relatively sparse geometric features. However, this technique cannot be used for doping a p-type impurity to the sidewalls of the trenches in the NMOS areas because of their dense geometric features. After the resist is removed, the wafer is coated with a boro-silicate glass (BSG) oxide layer. When a thermal oxidation process is performed, boron in the NMOS areas migrates from the BSG oxide layer to the trenches so that they are doped with a p-type impurity on their sidewalls and bottom to a depth much shallower than the depth of the n-type impurity doped region in the PMOS peripheral circuitry.

However, this technique cannot be used in the fabrication of a static RAM which is formed of CMOS structures since the skewed injection would produce an n-type impurity doped region in the trenches of PMOS cells to a depth much larger than is required. Since the NMOS cells are more severely affected by the channel region edge problem than the PMOS cells are, the migration of boron from the BSG oxide layer may be used for doping the trenches of the NMOS cells with a p-type impurity. However, it is difficult to prevent the PMOS cells from being doped with the same p-type impurity.

### SUMMARY OF THE INVENTION

It is therefore an object of the present invention to provide a semiconductor device and a method that prevents MOS transistors from having lowered threshold voltages and prevents variability of threshold voltages among different MOS transistors.

The stated object is attained by the provision of heavily doped impurity regions located respectively at opposite edge portions of each channel region of MOS transistor where adjacent isolation trenches are provided.

According to a first aspect of the present invention, there is provided a semiconductor device comprising a silicon substrate, a plurality of isolation trenches on the silicon substrate, each of the trenches being lined with a silicon nitride liner and filled with an insulating filler for isolating a plurality of MOS transistors from each other, and a plurality of impurity-doped channel regions for the MOS transistors in the substrate, each channel region extending between adjacent ones of the trenches, the channel regions having a conductivity type equal to conductivity type of the substrate and a concentration higher than a concentration of the substrate. A plurality of heavily doped impurity regions are formed in the substrate, wherein the heavily doped impurity regions form a pair for a corresponding one of the channel regions, are doped with a concentration higher than the concentration of the corresponding channel region, and are located respectively at opposite edges of the corresponding channel region close to adjacent ones of the trenches.

According to a second aspect, the present invention provides a method of fabricating a semiconductor device, comprising the steps of depositing silicon nitride layers on a silicon substrate to define a plurality of apertures corresponding to a plurality of areas where MOS transistors will be formed; depositing an impurity into the silicon substrate through the apertures to form impurity doped regions of the MOS transistors having a conductivity type identical to a conductivity type of the substrate and a concentration higher than a concentration of the substrate, forming spacers on opposite sidewalls of each of the apertures to define mask windows, etching the substrate through the mask windows to form a plurality of trenches, whereby center region of each impurity doped region is removed and two side regions thereof remain unaffected below the spacers and removing the spacers to form stepped shoulder portions on upper edges of each of the trenches and lining an area including the trenches and the stepped shoulder portions with a silicon nitride liner.

The method may further include the steps of depositing an isolation filler on the lined area, using hot phosphoric acid for etching the silicon nitride layers and portions of the silicon nitride liner that lie on the stepped shoulder portions to define areas where portions of the substrate and the side impurity doped regions are exposed, and removing portions of the filler and portions of the silicon nitride liner to form a surface flush with the defined areas.

The method may further include the steps of depositing an impurity into the defined areas to form channel regions having a conductivity type identical to the conductivity type of the substrate and a concentration higher than the concentration of the substrate and lower than the concentration of the side impurity doped regions, forming a plurality of gate insulators on the channel regions, and forming a plurality of gate electrodes of transistors on the channel regions and on side portions of the filled trenches.

### BRIEF DESCRIPTION OF THE DRAWINGS

The present invention will be described in detail further with reference to the following drawings, in which:

FIG. 1 is a cross-sectional view of a portion of a semiconductor wafer on which prior art MOS transistors of the shallow trench isolation structure are fabricated; and

FIGS. 2a to 2o are cross-sectional views of a portion of a semiconductor wafer for illustrating steps of fabricating NMOS transistors of the present invention on a p-type silicon substrate separated by a shallow trench isolation structure.

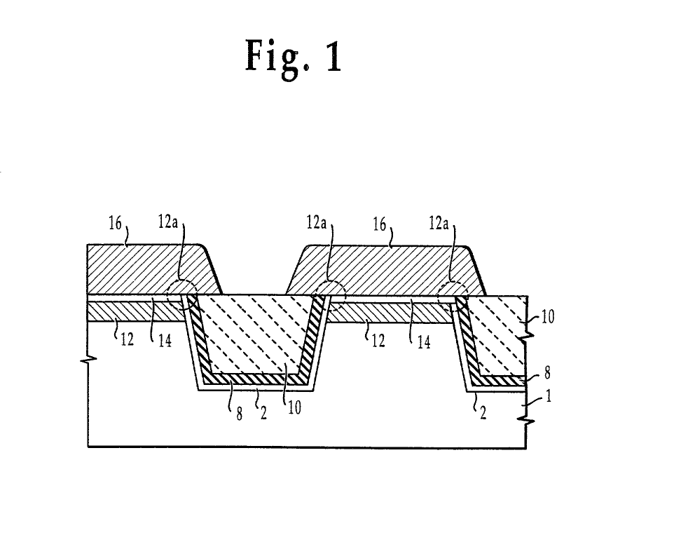

### DETAILED DESCRIPTION

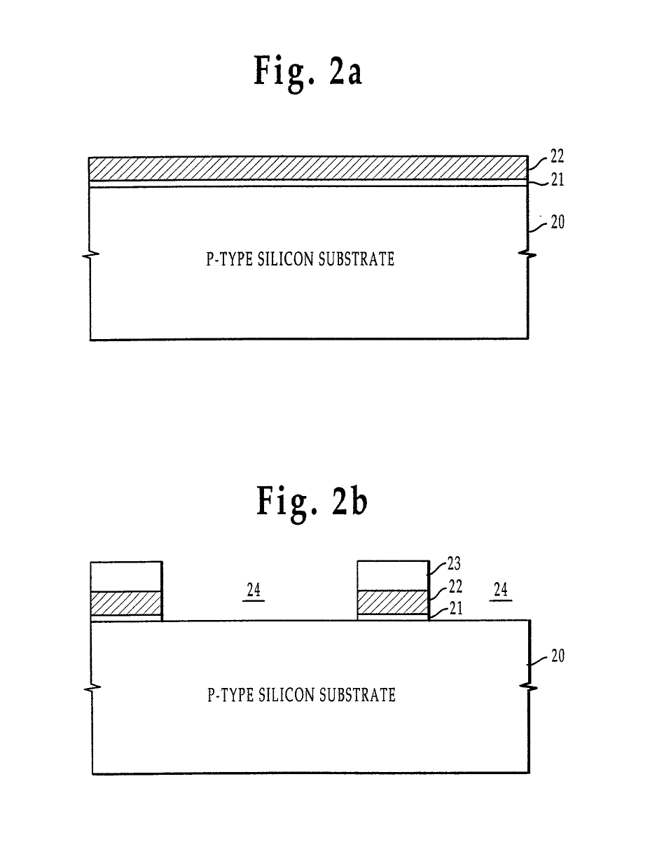

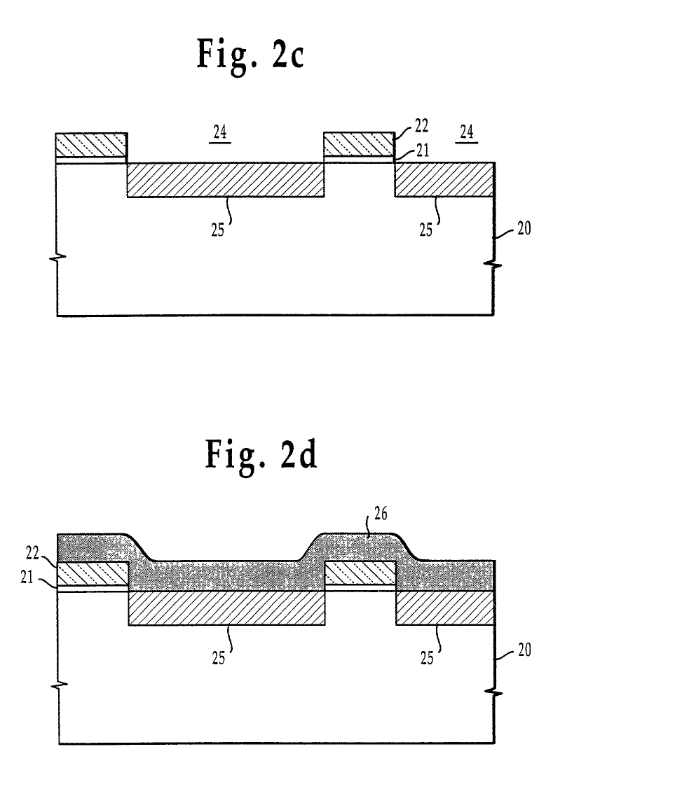

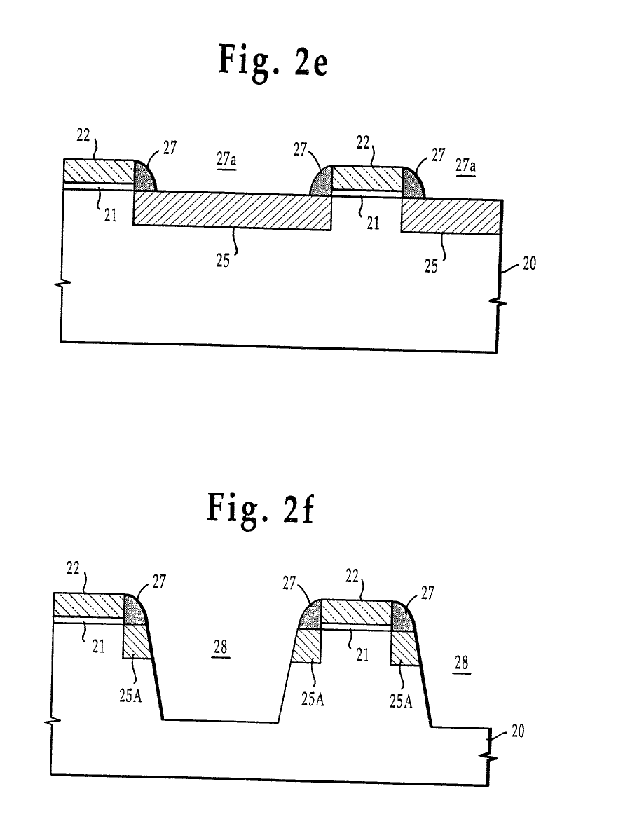

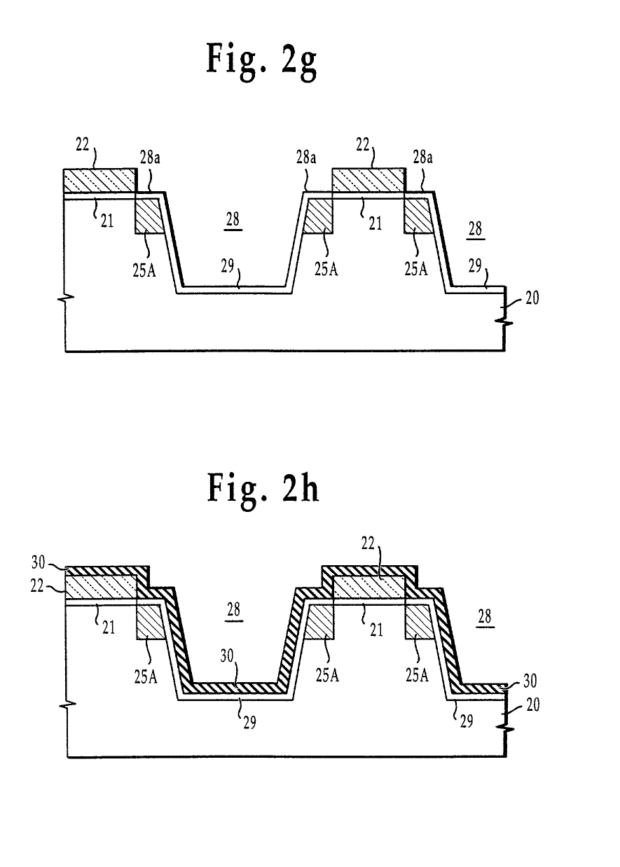

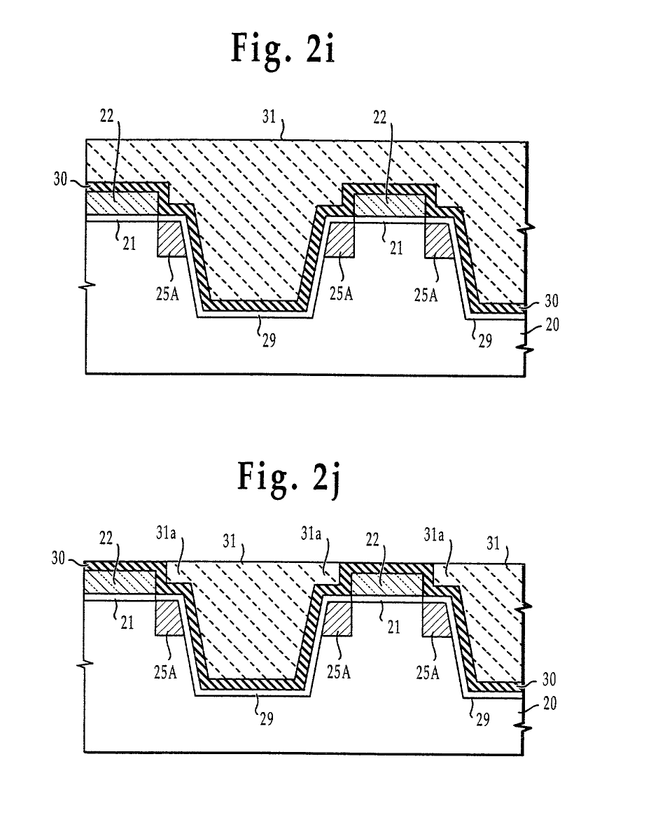

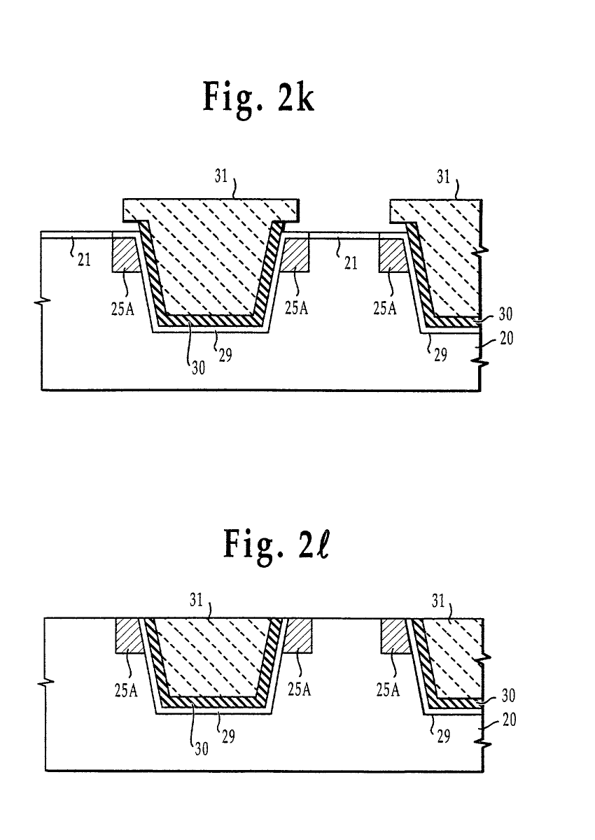

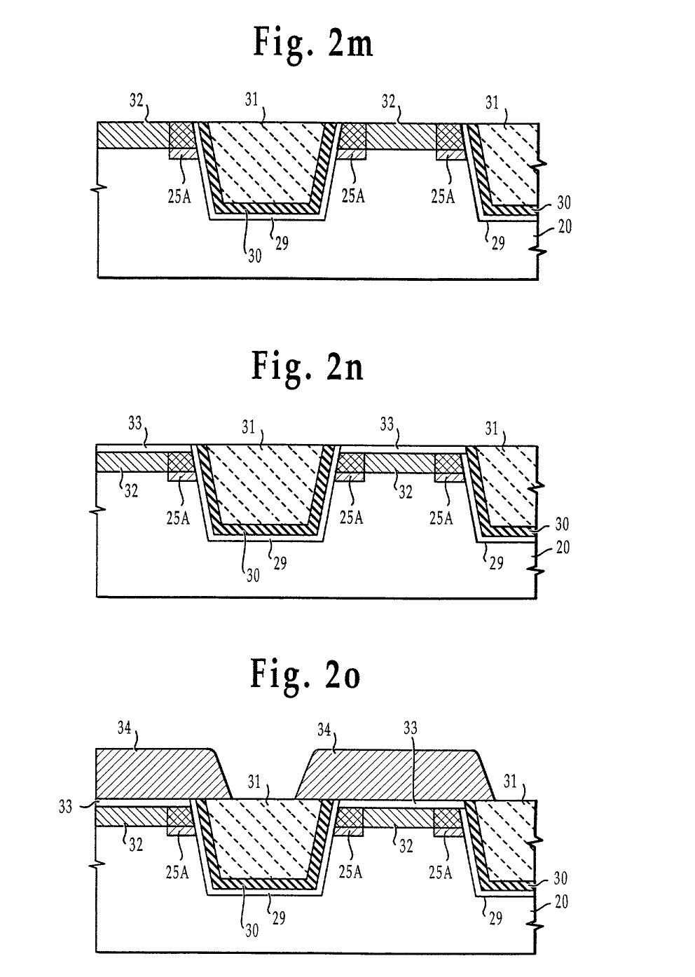

Referring to FIGS. 2a to 2o, there is shown a series of steps for fabricating on a silicon wafer an integrated circuit of NMOS transistors separated by a shallow trench isolation (STI) structure according to the present invention.

A thermal oxidation process is used to form a silicon dioxide layer 21 on the major surface of a silicon substrate 20 (FIG. 2a). The thermal oxidation process is continued until the layer 21 attains a thickness of 5 to 20 nm. On the silicon dioxide layer 21 is grown a silicon nitride layer 22 of thickness 100 to 300 nm using a chemical vapor deposition (CVD) process. The layers 21 and 22 are anisotropically dry-etched through a patterned resist 23 to form apertures 24 (FIG. 2b). Resist 23 is then removed and an ion implantation process is used to inject boron through the apertures 24 into the silicon substrate 20 to form p-type impurity doped regions 25 with a concentration higher than the concentration of p-type channel regions which will be formed later (FIG. 2c).

If the present invention is used to fabricate a static RAM, the resist 23 is first provided on all CMOS areas of the wafer to form the apertures 24 in both NMOS and PMOS areas and the resist 23 is removed. By masking the PMOS areas of the wafer, the whole wafer is subjected to an ion implantation process to form the p-type impurity doped regions 25 in the NMOS areas. Then, the PMOS areas are unmasked and the NMOS areas are masked instead, and the wafer is subjected to an ion implantation process to form n-type impurity doped regions similar to p-type impurity doped regions 25 on the PMOS areas.

A silicon dioxide layer 26 is then deposited over the surface of the wafer using the CVD method as shown in FIG. 2d. Silicon dioxide layer 26 is etched back anisotropically in a dry etching process so that portions of the layer 26 remain on the sidewalls of the apertures 24 as spacers 27 (FIG. 2e). Spacers 27 and the silicon nitride layers 22 define mask windows 27a. Preferably, the spacers 27 have a wall thickness of 30 to 50 nm as measured in lateral directions.

In FIG. 2f, the substrate 20 is anisotropically dry-etched through the mask window 27a to form isolation trenches 28 having a depth of 200 to 500 nm. As a result of the formation of each isolation trench 28, the center portion of each p-type impurity doped region 25 is removed, leaving side impurity doped regions 25A unaffected below the spacers 27. Therefore, each p-type impurity side region 25A has the same wall thickness of 30 to 50 nm as that of each spacer 27. Note that prior to this trench forming process, it is preferable to clean the wafer with diluted hydrofluoric acid to eliminate silicon residues which would otherwise be left in the trenches and to perform a drying process using the low pressure IPA (isopropyl alcohol) method.

Hydrofluoric acid solution is used to remove the spacers 27 and a thermal oxidation process is performed to line the isolation trenches 28 with a silicon dioxide liner 29 of thickness 5 to 15 nm, as shown in FIG. 2g, to remove the damage produced when the trenches were formed. In each of the trenches 28, the silicon dioxide liner 29 extends beyond the shoulder portions of the trench where the p-type impurity doped regions 25A are present until it meets the thermal oxide layers 21.

A chemical vapor deposition (CVD) process is then performed over the surface of the wafer to grow a silicon nitride layer so that the trenches 28 are lined with a silicon nitride liner 30 as shown in FIG. 2h. If the wall thickness of the spacers 27 is in the range between 30 and 50 nm, it can be ensured that the silicon nitride liner 30 has a desired thickness of 5 nm or greater which is necessary to guarantee its function.

Trenches 28 are filled with a silicon dioxide filler by depositing a silicon dioxide layer 31 over the wafer by using a CVD process, as shown in FIG. 2i.

An annealing step is subsequently performed for densifying the silicon oxide fillers 31. A chemical mechanical polishing or etchback process is then used to planarize the wafer until upper portions of the silicon nitride liner 30 are exposed to the outside as shown in FIG. 2j. It is seen that, due to the outwardly stepped shoulders 28a, the upper portions of silicon dioxide fillers 31 are shaped into overhanging portions 31a and the silicon nitride layers 22 have their edges positioned outwards of the trenches 28.

In a subsequent stripping process, the exposed portions of silicon nitride liners 30 and the silicon (pad) nitride layers 22 are removed by using hot phosphoric acid, as shown in FIG. 2k. Since each silicon nitride liner 30 extends laterally some distance below the overhanging portions 31a, the hot phosphoric acid takes time to penetrate laterally below the overhanging portions 31a until it reaches the upper edge portions of the trench liner 30. Therefore, when the stripping process is complete, the head of the penetration stops at a point short of the upper edges of the liner 30. This prevents unacceptable recesses which would otherwise be produced at the upper edges of the trench liner 30 by the penetrating hot phosphoric acid. To avoid this problem the prior art required that the thickness of the silicon nitride liner should be smaller than 5 nm.

FIG. 2l shows the result of a further stripping process in which the silicon dioxide layers 22 and the portions of fillers 31 that lie above the general surface of the wafer are removed by hydrofluoric acid solution until the wafer attains a substantially flat surface. In this way, portions of the substrate 20 and the side impurity doped regions 25A are exposed to the outside, and an area is defined in which impurity will be deposited to create channel regions for NMOS transistors. Hot phosphoric acid may be further used to remove portions of the trench liners 30 which may extend above the surface of the wafer.

Conventional techniques will then be used to form p-type channel regions, gate oxide layers, a gate electrode, source and drain electrodes.

Specifically, as shown in FIG. 2m, p-type channel regions 32 are formed by injecting boron into the p-type substrate 20 through a patterned mask by ion implantation technique. Each p-type channel region 32 laterally extends between two p-type impurity doped regions 25A in the direction of its width and are injected to a depth shallower than the depth of side p-type impurity doped regions 25A. Further, each channel region 32 has an impurity concentration lower than that of the side impurity doped regions 25A but higher than that of the substrate 20. Each channel region 32 has therefore a heavily doped region of the same conductivity type at each end of its channel width.

A thermal oxidation process is then performed to form gate oxide layers 33 as shown in FIG. 2n. The thermal oxidation process is followed by deposition of polysilicon and metal suicides to form gate electrodes 34 as shown in FIG. 2o. Although not shown in FIG. 2o, source and drain electrodes are formed for each gate electrode 34 in the substrate 20, one at the far end of the length of channel region 32 and the other at the near end.

Since an NMOS transistor is formed with heavily doped impurity doped regions 25A, the present invention prevents the lowering of its threshold voltage along the edges of its channel region near the trench. Variability of threshold voltages among different NMOS transistors is also prevented.

What is claimed is:

1. A semiconductor device comprising:
a silicon substrate;
a plurality of isolation trenches on said silicon substrate, each of the trenches being lined with a silicon nitride liner and filled with an insulating filler for isolating a plurality of MOS transistors from each other;
a plurality of impurity-doped channel regions of said MOS transistors in said substrate, each channel region extending between adjacent ones of said trenches, said channel regions having a conductivity type equal to conductivity type of said substrate and a concentration higher than a concentration of said substrate; and
a plurality of heavily doped impurity regions in said substrate, wherein said heavily doped impurity regions form a pair for a corresponding one of said channel regions, are doped with a concentration higher than the concentration of the corresponding channel region, and are located respectively at opposite edges of the corresponding channel region close to adjacent ones of said trenches.

2. The semiconductor device of claim 1, wherein said liner is formed of silicon nitride and wherein the liner has a thickness equal to or greater than 5 nm.

3. The semiconductor device of claim 1, wherein each of said heavily doped regions has a depth greater than a depth of said channel regions.

4. The semiconductor device of claim 1, wherein each of said heavily doped regions has a wall thickness of 30 to 50 nm.

5. The semiconductor device of claim 3, wherein each of said heavily doped regions has a wall thickness of 30 to 50 nm.

6. The semiconductor device of claim 3, wherein each of said heavily doped regions has a depth greater than a depth of said channel regions.

7. A method of fabricating a semiconductor device, comprising the steps of:
a) depositing silicon nitride layers on a silicon substrate to define a plurality of apertures corresponding to a plurality of areas where MOS transistors will be formed;
b) depositing an impurity into said silicon substrate through said apertures to form impurity doped regions for said MOS transistors having a conductivity type identical to a conductivity type of said substrate and a concentration higher than a concentration of said substrate;
c) forming spacers on opposite sidewalls of each of said apertures to define mask windows;
d) etching said substrate through said mask windows to form a plurality of trenches, whereby center region of each of said impurity doped regions is removed and two side regions thereof remain unaffected below said spacers; and
e) removing said spacers to form stepped shoulder portions on upper edges of each of said trenches and lining an area including said trenches and said stepped shoulder portions with a silicon nitride liner.

8. The method of claim 7, further comprising the steps of:
f) depositing an isolation filler on said lined area;
g) using hot phosphoric acid for etching said silicon nitride layers and portions of said silicon nitride liner that lie on said stepped shoulder portions to define areas where portions of the substrate and said side impurity doped regions are exposed; and
h) removing portions of the filler and portions of the silicon nitride liner (30) to form a surface flush with said defined areas.

9. The method of claim 8, further comprising the steps of:
i) depositing an impurity into said defined areas to form channel regions having a conductivity type identical to the conductivity type of said substrate and a concentration higher than the concentration of the substrate and lower than the concentration of said side impurity doped regions;
j) forming a plurality of gate insulators on said channel regions; and
k) forming a plurality of gate electrodes of transistors on said channel regions and on side portions of said filled trenches.

10. The method of claim 7, wherein step (e) further comprises lining said area with a thermal oxide layer before lining said area with said silicon nitride liner.

11. The method of claim 7, wherein said silicon nitride liner has a thickness equal to or greater than 5 nm.

12. The method of claim 7, wherein each of said spacers has a wall thickness of 30 to 50 nm.

13. The method of claim 7, wherein step (c) comprises the steps of depositing a silicon dioxide layer on said silicon substrate and anisotropically etching the silicon dioxide layer in an etchback process to form said spacers.

14. The method of claim 9, wherein said MOS transistors comprise a plurality of NMOS transistors and a plurality of PMOS transistors, and wherein step (b) further comprises the steps of masking a first plurality of areas of said substrate where said PMOS transistors will be formed and performing step (b) to deposit p-type impurity into a second plurality of areas of said substrate where NMOS transistors will be formed.

15. The method of claim 14, wherein step (b) further comprises the steps of masking said second first plurality of areas and performing step (b) to deposit n-type impurity into said first plurality of areas where PMOS transistors will be formed.
